(19) United States
(12) Patent Application Publication
(10) Pub. No.: US 2012/0192915 A1
(43) Pub. Date: Aug. 2, 2012

(54) PHOTOVOLTAIC MODULE AND ARRAY AND METHOD OF MANUFACTURE THEREOF

(75) Inventors: Yael Alali, Tel Aviv (IL); Itay Baruchi, Tel-Aviv (IL); Michael Ben-Dor, Hod Hasharon (IL); Barak Freedman, Binyamina (IL)

(73) Assignee: PYTHAGORAS SOLAR INC., Wilmington, DE (US)

(21) Appl. No.: 13/500,850

(22) PCT Filed: Oct. 7, 2010
(86) PCT No.: PCT/IL2010/000817

§ 371 Date: Apr. 6, 2012

(30) Foreign Application Priority Data
Oct. 7, 2009 (US) 61249485

(51) Int. Cl. H01L 31/05; H01L 31/02

(52) U.S. Cl. 136/244; 438/66; 257/E31.113

(57) ABSTRACT

A method for manufacture of a photovoltaic module is provided, the method comprising providing one or more photovoltaic (PV) cells, each being configured to convert incident light into electrical energy, providing a printed circuit board (PCB) configured to electrically connect the PV cells to each other, disposing the PV cells on the PCB, providing a solder paste between the electrically conductive portions of the PV cells and PCB, and heating the PV cells and PCB to a temperature sufficient to melt the solder paste, thereby soldering the PV cells to the PCB.

### FIELD OF THE INVENTION

This invention relates to photovoltaic modules, and in particular to photovoltaic modules comprising a plurality of photovoltaic cells.

### BACKGROUND OF THE INVENTION

It is well known that solar radiation can be utilized by various methods to produce useable energy. One method involves the use of a photovoltaic cell, which is configured to convert solar radiation to electricity. Solar radiation collectors are typically used to gather sunlight or other radiation and direct it toward a photovoltaic cell. Often, concentrators are provided in order to focus the radiation from an area to a photovoltaic cell which is significantly smaller than the area.

Often, a plurality of photovoltaic cells is provided to form a single module. One or more of these modules may be deployed at a location. The individual cells and modules are connected to one another using various topologies which are well known, each of which is associated with particular advantages.

### SUMMARY OF THE INVENTION

According to one aspect of the present invention, there is provided a method for manufacture of a photovoltaic module, the method comprising:
providing one or more photovoltaic (PV) cells, each being configured to convert incident light into electrical energy;
providing a printed circuit board (PCB) configured to electrically connect the PV cells to each another;
disposing the PV cells on the PCB;
providing a solder paste between the electrically conductive portions of the PV cells and PCB; and
heating the PV cells and PCB to a temperature sufficient to melt the solder paste, thereby soldering the PV cells to the PCB.

The disposing may comprise arranging at least some of the PV cells such that end portions thereof overhang areas free of material of the PCB. The PCB may comprise a pair of through-going apertures (which constitute the areas free of material of the PCB) adjacent one another, giving rise to one or more cell-carrying portions therebetween, and wherein the disposing comprises disposing at least some of the PV cells on at least one of the cell-carrying portions such that end portions of the PV cell are disposed over the through-going apertures.

The method may further comprise providing a heat-dissipation element disposed on a side of the PCB opposite that carrying the PV cells, and bringing the heat-dissipation element into thermal contact with the PV cells via the through-going apertures.

The PV cells may be configured such that they undergo thermally-induced deformation in a direction away from the PCB when mounted thereupon; i.e., when they undergo heating sufficient to melt the solder paste, they bend such that the free ends thereof move away from the PCB.

The method may further comprise mounting, prior to the heating, the PV cells to the PCB using an adhesive, which may be a pressure-sensitive adhesive, having sufficient strength to maintain the PV cells on the PCB when the PV cells undergo thermally-induced deformation, due to the heat associated with the soldering, tending to detach them from the PCB.

The PCB may comprise a heat-dissipation layer.

Each of the cells may comprise, on a first, PCB-facing face thereof, a lower contact pad, and, on a second face opposite the first face, an upper contact pad, the contact pads being electrically connected to an electrically conductive layer of the PCB.

The upper contact pad may be electrically connected to the PCB via a connection member configured to maintain a mechanical connection to the PV cell and PCB during thermal expansion thereof.

The connection member may be made of a solid, electrically conductive material comprising one or more slots formed therein, and/or at least partially formed as a mesh. Alternatively, the connection member may be constituted by solder paste.

The PV cells may comprise two lower contact pads, which may be formed within 10 mm of one another.

The PV cells comprise two or more fiducial markers configured for facilitating automated placement of the cell on the PCB during manufacture of the module.

Each of the PV cells may have a surface area which is less than 8 cm², and/or a length which is less than 27 mm.

The module may be configured to concentrate incident light by a factor not exceeding 10, and may be free of any concentration optics.

The PCB may be configured to connect the PV cells in a total cross-tie topology.

The module may comprise one or more bypass diodes.

The module may comprise a logic circuit element, which may be selected from the group consisting of an application-specific integrated circuit and a field-programmable gate array. The logic circuit element may be configured to perform one or more of the following functions:
facilitate optimal connection of the PV cells according to real-time conditions; and
monitor a single cell or group of cells.

The module may be free of a tracking mechanism and/or an active cooling arrangement.

According to another aspect of the present invention, there is provided a method for manufacture of a photovoltaic array, the method comprising:
providing a plurality of photovoltaic modules, each manufactured as described above;
providing one or more support members carrying the modules, the support members being constituted by PCBs and being configured to electrically connect the modules; and
mechanically mounting and electrically connecting the photovoltaic arrays to the support member.

Each of the modules may comprise one or more connectors, with each of the support members comprising notches configured to receive the connectors.

Each of the support members may comprise a connection point to an electrically conductive layer thereof adjacent each of the notches, being disposed to contact a corresponding electrically conductive portion of the connector.

The method may further comprise:
providing two of the support members spaced from and disposed parallel to and spaced from one another; and
mounting the modules such that they span between the support members.

According to a further aspect of the present invention, there is provided photovoltaic module comprising one or more photovoltaic (PV) cells, each being configured to convert incident light into electrical energy, soldered to a printed circuit board (PCB) configured to electrically connect the PV cells to each other, wherein the PV cells and PCB are so configured and connected such that the module can withstand heating to a temperature sufficient to perform the soldering.

The PV cells may be connected such that ends thereof overhang areas free of material of the PCB. The PCB may comprise a pair of through-going apertures adjacent one another, giving rise to one or more cell-carrying portions therebetween, each carrying a PV cell, end portions of the PV cells being disposed over or within the through-going apertures. A heat-dissipation element disposed on a side of the PCB opposite that carrying the PV cells may further be provided, the heat-dissipation element contacting the PV cells via the through-going apertures.

The PV cells may be configured such that they undergo thermally-induced deformation in a direction away from the PCB when mounted thereupon; i.e., when they undergo heating sufficient to melt the solder paste, they bend such that the free ends thereof move away from the PCB.

The PV cells may be mounted to the PCB with an adhesive, which may be a pressure-sensitive adhesive, having sufficient strength to maintain the PV cells on the PCB when the PV cells undergo thermally-induced deformation, due to the heat associated with the soldering, tending to detach them from the PCB.

The PCB may comprise a heat-dissipation layer.

Each of the cells may comprise, on a first, PCB-facing face thereof, a lower contact pad, and, on a second face opposite the first face, an upper contact pad, the contact pads being electrically connected to an electrically conductive layer of the PCB.

The upper contact pad may be electrically connected to the PCB via a connection member configured to maintain a mechanical connection to the PV cell and PCB during thermal expansion thereof.

The connection member may be made of a solid, electrically conductive material comprising one or more slots formed therein, and/or at least partially formed as a mesh. Alternatively, the connection member may be constituted by solder paste.

The PV cells may comprise two lower contact pads, which may be formed within 10 mm of one another.

The PV cells comprise two or more fiducial markers configured for facilitating automated placement of the cell on the PCB during manufacture of the module.

Each of the PV cells may have a surface area which is less than 8 cm², and/or a length which is less than 27 mm.

The module may be configured to concentrate incident light by a factor not exceeding 10, and may be free of any concentration optics.

The PCB may be configured to connect the PV cells in a total cross-tie topology.

The module may comprise one or more bypass diodes.

The module may comprise a logic circuit element, which may be selected from the group consisting of an application-specific integrated circuit and a field-programmable gate array. The logic circuit element may be configured to perform one or more of the following functions:
facilitate optimal connection of the PV cells according to real-time conditions; and
monitor a single cell or group of cells.

The module may be free of a tracking mechanism and/or an active cooling arrangement.

According to a still further aspect of the present invention, there is provided a photovoltaic array comprising a plurality of photovoltaic modules as described above, and one or more support members carrying the modules, the support members being constituted by PCBs and being configured to electrically connect the modules.

Each of the modules may comprise one or more connectors, with each of the support members comprising notches configured to receive the connectors.

Each of the support members may comprise a connection point to an electrically conductive layer thereof adjacent each of the notches, being disposed to contact a corresponding electrically conductive portion of the connector.

The photovoltaic array may further comprise two of the support members spaced from and disposed parallel to one another, with the modules being mounted thereon such that they span therebetween.

### BRIEF DESCRIPTION OF THE DRAWINGS

In order to understand the invention and to see how it may be carried out in practice, embodiments will now be described, by way of non-limiting examples only, with reference to the accompanying drawings, in which:

FIG. 1 is a perspective view of a photovoltaic module according to the present invention;

FIGS. 2A and 2B are, respectively, top and bottom perspective views of a photovoltaic cell of the photovoltaic module illustrated in FIG. 1;

FIG. 3A is a perspective view of a printed circuit board of the photovoltaic module illustrated in FIG. 1;

FIG. 3B is a cross-sectional view taken along line in FIG. 3A;

FIG. 4A is a top view of the photovoltaic cell illustrated in FIGS. 2A and 2B disposed on the printed circuit board illustrated in FIG. 3A;

FIG. 4B is a side view of the photovoltaic cell mounted on the printed circuit board;

FIG. 5A illustrates another example of a printed circuit board according to the present invention;

FIG. 5B illustrates a photovoltaic module assembled using the printed circuit board illustrated in FIG. 5A;

FIG. 6A is a partial side view illustrating a connection between the cell and the printed circuit board, including placement of a top connection member connecting therebetween;

FIGS. 6B and 6C are top views of different examples of the top connection member illustrated in FIG. 6A;

FIG. 6D is a partial side view illustrating another example of a connection between the cell and the printed circuit board;

FIG. 7A is a perspective view of a photovoltaic array according to the present invention;

FIG. 7B is a side view of a vertical support member of the photovoltaic array illustrated in FIG. 7A; and

FIG. 8 is a schematic electrical diagram of one example of a solar array.

### DETAILED DESCRIPTION OF EMBODIMENTS

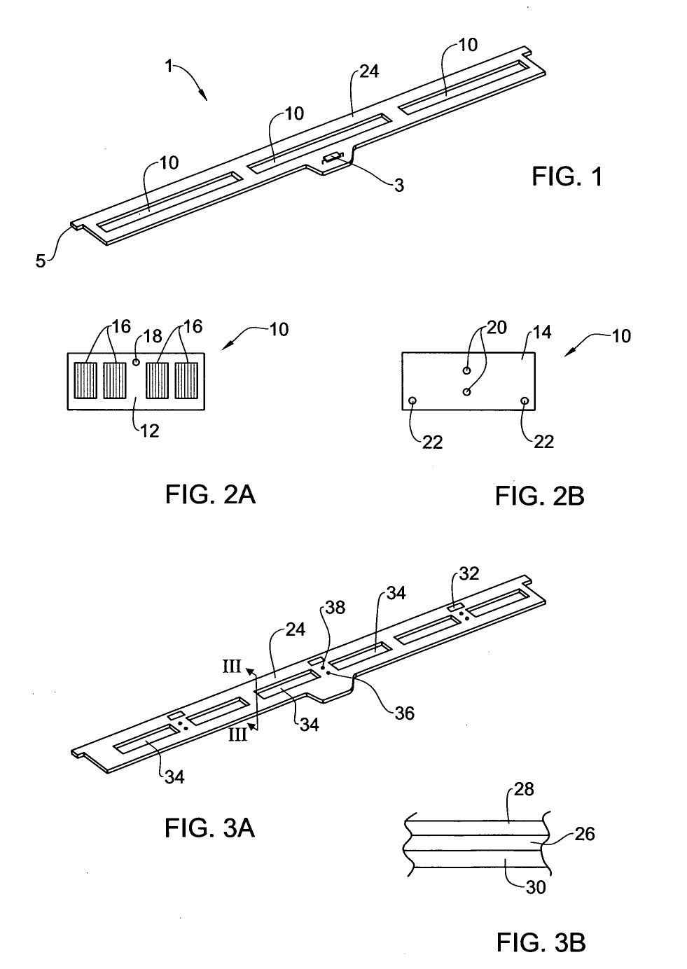

As illustrated in FIG. 1, there is provided a photovoltaic (PV) module, which is generally indicated at 1. The PV module 1 comprises a plurality of PV cells 10 mounted on a printed circuit board (PCB) 24.

The PV cell 10 is configured to convert incident light into electrical energy, and to be mounted to the printed circuit board 24. The PCB is configured to electrically connect among the PV cells 10 mounted thereon.

The module 1 may further comprise one or more bypass diodes 3, connected in parallel to one or more of the cells 10. In addition, connectors 5 are provided, for example one at each end of the module, in order to facilitate mechanical and/or electrical connection of the module to a separate element.

As illustrated in FIGS. 2A and 2B, the PV cell 10 comprises a top surface 12 and a bottom surface 14. The top surface 12 is configured to be impinged upon by incident light, and the bottom surface 14 is configured to be mounted to the PCB.

The cell 10 is relatively small in size, for example having a surface area which is less than about 8 cm², an optionally having a length which is less than about 27 mm (i.e., for a rectangular cell, the longer of the length and width is less than about 27 mm; the length of the diagonal may be larger than about 27 mm). This size suits the cell 10 for use with automated surface mount technology (SMT) machines, and in particular those which utilize tape-and-reel and revolver system. It will be appreciated that these dimensions are based on suitability for currently available SMT machines, and may therefore be altered if necessary according to the requirements of any other SMT machine.

In the event that a vacuum nozzles are used to pick the cells 10 from a tray for placement thereof on the PCB, the size of each cell may be larger. However, such a system does not allow for manufacturing at speeds allowed by a tape-and-reel and revolver system.

Although the cell 10 size may be limited to smaller than about 8 cm² in surface area, it will be appreciated that, within this limitation and taking other design considerations into account, the ratio of the length of the edge of the cell to the surface area of the cell should be as small as possible. Therefore, the cell 10 is not designed to be unnecessarily small.

In order to prevent heating of the cell 10 during use thereof to a temperature above which the PCB is designed to withstand, it is free of high-concentration optics. Specifically, it is either free of any concentration optics, or provided with low-concentration optics, which are configured to concentrate light up to about ten times.

The top surface 12 of the PV cell 10 is formed with one or more PV active areas 16, each of which comprises a PV material which accomplishes the conversion of light into electrical energy. The PV material may be any material known to be useful for this purpose, including, but not limited to, silicon (which may be monocrystalline, polycrystalline, or amorphous), cadmium telluride, or copper indium selenide/sulfide.

In addition, the top surface comprises an upper contact pad 18, the purpose of which will be explained below. It will be appreciated that the cell described with reference to FIG. 2A is a “front-contact cell”, which comprises one of its electrical contacts on the radiation-facing surface. The cell 10 may be provided as a “rear-contact cell”, in which case the upper contact pad 18 will be absent.

The bottom surface 14 of the PV cell 10 comprises one or more lower contact pads 20. As these contact pads 20 function, inter alia, to physically connect the cell 10 to the PCB, two or more contact pads 20 may be provided in order to ensure stability of the cell 10 once mounted, irrespective of whether the cell is configured as a “front-contact cell” or a “back-contact cell”. In such a case, the cell 10 is designed such that the lower contact pads 20 are sufficiently close to one another to mitigate the effects of the different rates of thermal expansion between the cell 10 and the PCB during heating and cooling. For example, the distance between the lower contact pads 20 may be less than about 10 mm. However, it will be appreciated that this distance be more or less, depending on the materials of the cell 10 and PCB, the temperatures to be used during soldering, etc., as is well known in the art.

As the cell 10 will be assembled to other cells and the PCB using SMT soldering techniques, the upper and lower contact pads 18, 20 are designed such that they are large enough to allow for a robust soldering.

In addition, the bottom surface 14 of the PV cell 10 comprises two or more fiducial markers 22, which are used by the SMT machine in order to properly position the cell relative to the PCB. Although the fiducial markers 22 illustrated are in the form of rings, it will be appreciated that any appropriate shape may be used. In addition, it will be appreciated that the location of the fiducial markers 22 shown is for illustration only; in practice, the designer may provide fiducial markers at any appropriate location.

Alternatively, the lower contact pads 20 may function as fiducial markers, either by themselves, or together with other fiducial markers formed on the bottom surface 14 of the cell 10. Separate fiducial markers or portions thereof (not illustrated) may be present on the cell 10 as artifacts from the dicing process, wherein the PV cell 10 was cut from a larger wafer.

The cell 10 further comprises one or more metallization layers, in electrical contact with both the PV active areas 16 and upper and lower contact pads 18, 20, configured to carry electricity produced by the PV active area to the contact pads, from where the electricity produced is carried from the cell for use.

As illustrated in FIG. 3A, the PCB, which is generally indicated at 24, is provided. It is constructed according to any appropriate design which will electrically connect between the PV cells 10 mounted thereupon and facilitate the mounting thereof using an automated SMT technique to from the module. As such, and as illustrated in FIG. 3B, the PCB 24 may comprise an electrically conductive layer 26 defining the circuit topology and configured to carry the electricity generated by the PV cells 10, sandwiched between top and bottom non-conductive layers 28, 30. The top non-conductive layer 28 comprises openings 32 (seen in FIG. 3A) providing access for the cells 10 to be connected to the electrically conductive layer.

Optionally, the PCB may be formed as a metal-core PCB (MCPCB), comprising an additional layer (not illustrated) for heat dissipation. The additional layer may be made of any appropriate material, such as aluminum, and is electrically isolated from the conductive layer 26.

The electrically conductive layer 26 is provided so as to connect the cells 10 in any desired connection topology, including in parallel, series, total cross-tie (TCT), etc. The use of the PCB 24 to connect among the PV cells 10 mounted thereon thus permits connecting between a large number of PV cells 10, even according to complicated topologies, in an automated fashion.

The PCB further may comprises through-going apertures 34 arranged in pairs, giving rise to a cell-carrying bridge 36 defined therebetween. The cell-carrying bridge is configured for attachment to the lower contact pads 20 of a cell 10, and thus comprises a number of points 38 equal in number to and arranged in accordance with the lower contact pads. Although not illustrated, additional through-going apertures may be associated with each cell-carrying bridge 36.

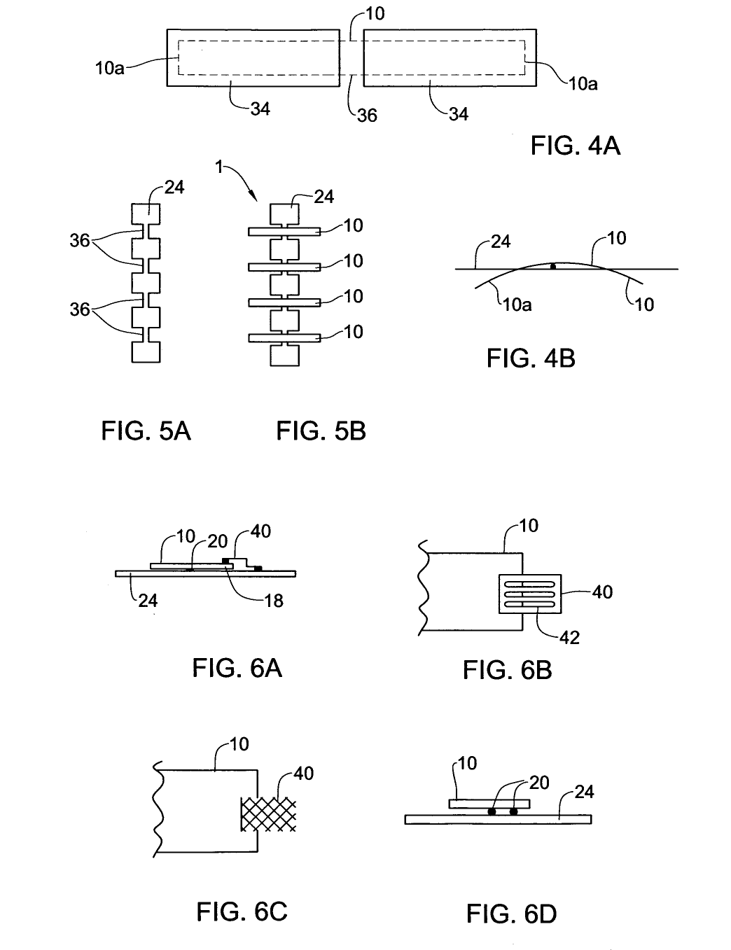

As illustrated in FIG. 4A, the through-going apertures 34 and cell-carrying bridge 36 are co-designed so as to allow bending of the cell 10 (illustrated in phantom lines) during manufacture. Thus, each is sized slightly larger than the portion of the cell 10 which overhangs it, such that when the cell bends, as illustrated in FIG. 4B, it may pass therethrough with a small clearance space, e.g., in order to allow for a margin of error in placement of the cell on the cell-carrying bridge 36, some lateral motion of the cell such as due to bending, etc.

During soldering, for example reflow soldering, of the cells 10 to the PCB 24, the cell will reach a very high temperature, and is subject to bending. In order to prevent free portions of the cell, e.g., ends 10a thereof, from contacting and/or bearing against the PCB, thus giving rise to a force which would tend to break the bond between the lower contact pads 20 of the cell, the cell is positioned such that its ends pass through the through-going apertures 34 during this bending. In this way, the cell 10 is allowed to bend naturally, without creating any additional forces thereupon, which may, inter alia, break the bond between it and the PCB 24.

As an alternative to providing the through-going apertures 34, the cell 10 may be temporarily mounted, before soldering, to the PCB 24 using an adhesive, such as a pressure-sensitive adhesive. The adhesive and the amount used is selected such that when the cell 10 undergoes thermally-induced bending as described above, the adhesive will be strong enough to overcome the force resulting thereon due to the bearing of the ends 10a of the cell on the PCB. Once the soldering is complete, the adhesive is no longer necessary, but may remain in place.

In addition to the utility of the through-going apertures 34 during assembly, they further permit application of a thermal paste on the back of the cells 10, so that heat from the cell could be more efficiently transferred to the optional additional heat dissipation layer of the PCB, if provided.

As illustrated in FIGS. 5A, the PCB 24 may comprise a series of cell-carrying bridges 36 connected to one another, thus forming a chain of bridges extending in a first direction. As seen in FIG. 5B, cells 10 may be mounted to such a PCB to form the module 1 such that they overhang in a second direction perpendicular to the first direction. Such an arrangement reduces the size of the PCB, thereby reducing the cost thereof.

According to any of the arrangements described with reference to FIGS. 3A through 5B, the PCB 24 is designed such that the cell 10 may be mounted thereto such that free ends 10a thereof overhang an area free of material of the PCB, i.e., in such a manner that the ends of the cell may bend toward the PCB without contacting it.

Prior to soldering of the cell 10 to the PCB 24, an adhesive may be applied in order to at least temporarily affix the cell to the PCB. The adhesive should be selected such that within the temperature range reached during soldering it maintains an elasticity sufficient to compensate for the difference in thermal expansion between the cell 10 and the PCB 24. Although the adhesive may no longer be necessary after the soldering has taken place, it may be left in position.

According to any of the designs of PCB 24 described above, when a “front-contact cell” constitutes the PV cell 10, a top connection member 40 may be provided, as illustrated in FIG. 6A, to electrically connect the upper contact pad 18 to the PCB, specifically to an appropriate portion of the electrically conductive layer 26 thereof.

The top connection member 40 is made of an electrically conductive material, such as a bent piece of metal or a large amount of solder paste, or any other appropriate material. As illustrated in FIGS. 6B and 6C, in the event that the top connection member 40 is made of a solid material such as metal, it may be formed so as to mitigate the effect of differences in thermal expansion between any two or more of itself, the cell 10, and the PCB 24. For example, as seen in FIG. 6B, it may be formed with slots 42 formed therein, in any configuration (it will be appreciated that the slots illustrated in the accompanying figure are for illustration only; in practice, the slots may be formed in any direction or in more than one direction, at the discretion of the designer, without departing from the scope of the present invention, mutatis mutandis). Alternatively, as seen in FIG. 6C, the top connection member 40 may be formed as, or comprise a portion formed as, a mesh material, providing the required flexibility.

As illustrated in FIG. 6D, according to any of the designs of PCB 24 described above, when a “back-contact cell” constitutes the PV cell 10, the lower contact pads 20 are soldered directly to appropriate portions of the electrically conductive layer 26 thereof.

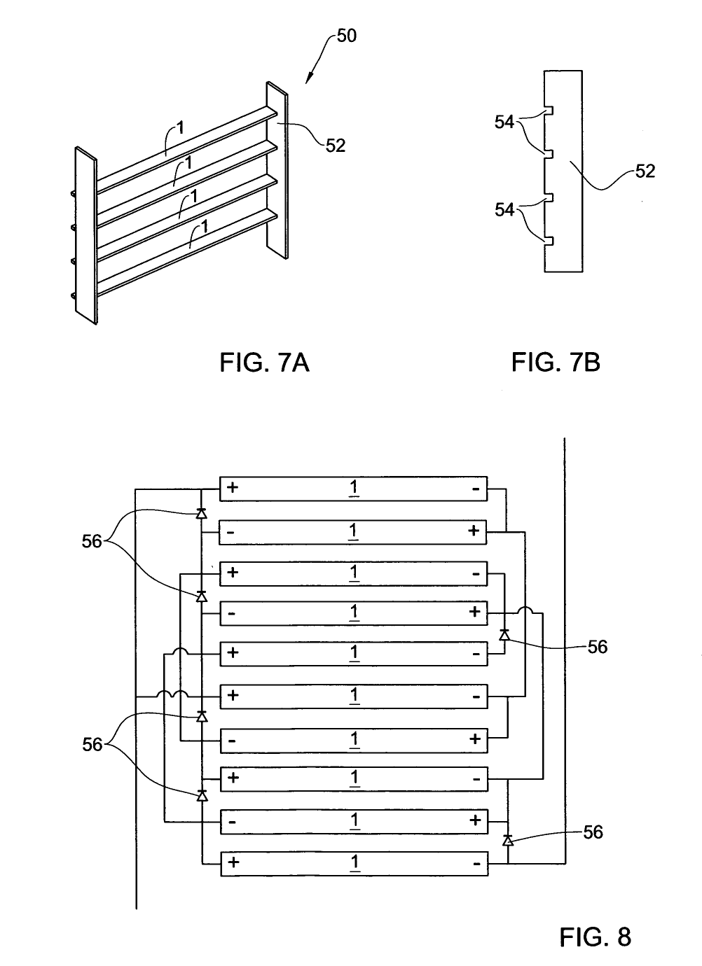

As illustrated in FIG. 7A, a three dimensional solar array, which is generally indicated at 50, may be constructed using several modules as constructed above. The array 50 comprises two vertical support members 52 disposed substantially parallel to and spaced from one another, carrying a plurality of the modules 1 described above, spanning substantially perpendicularly therebetween.

Each vertical support member 52 is constituted by a PCB, and, as illustrated in FIG. 7B, comprises a plurality of notches 54 formed therein, each configured for receiving one of the connectors 5 of a module 1. In addition, an electrically conductive layer of the vertical support member 52 has a connection point adjacent each notch 54 which is disposed to as to contact a corresponding electrically conductive portion of the connector 5. In this way, the vertical support members 52 can be used to assemble several modules 1 into the array 50, which functions as a single mechanical and electrical unit.

For example, the vertical support members 52 may be used to connect the modules 1 in a TCT configuration, as schematically illustrated in FIG. 8. It will be appreciated that the vertical support members 52 may comprise appropriate circuit elements, such as diodes 56, in order to support the chosen circuit topology. As further seen in FIG. 8, at least some of the modules 1 may be connected to the vertical support members 52 such that their polarities alternate.

In addition to the above, programmable or pre-programmed logic may be provided, for example in the form of an application-specific integrated circuit (ASIC) or field-programmable gate array (FPGA) circuit element. Such logic may facilitate optimal connection of the cells 10 according to real-time conditions, monitoring of a single cell or group of cells, etc.

Those skilled in the art to which this invention pertains will readily appreciate that numerous changes, variations and modifications can be made without departing from the scope of the invention mutatis mutandis.

1-62. (canceled)

63. A method for manufacture of a photovoltaic module, the method comprising:
(a) providing one or more photovoltaic (PV) cells, each being configured to convert incident light into electrical energy;
(b) providing a printed circuit board (PCB) configured to electrically connect said PV cells to each another;
(c) disposing said PV cells on the PCB;
(d) providing a solder paste between said electrically conductive portions of the PV cells and PCB; and
(e) heating the PV cells and PCB to a temperature sufficient to melt the solder paste, thereby soldering the PV cells to the PCB.

64. A method according to claim 63, wherein the method constituting part of an automated surface mount technology.

65. A method according to claim 64, wherein said PCB comprises a pair of through-going apertures adjacent one another, giving rise to one or more cell-carrying portions therebetween, and wherein said disposing comprises disposing at least some of said PV cells on at least one of said cell-carrying portions such that end portions of the PV cell are disposed over said through-going apertures.

66. A method according to claim 63, further comprising mounting, prior to said heating, the PV cells to the PCB using an adhesive having sufficient strength to maintain the PV cells on the PCB when the PV cells undergo thermally-induced deformation, due to the heat associated with the soldering, tending to detach them from the PCB.

67. A method according to claim 63, wherein each of the cells comprises, on a first, PCB-facing face thereof, a lower contact pad, and, on a second face opposite the first face, an upper contact pad, said contact pads being electrically connected to an electrically conductive layer of the PCB.

68. A method according to claim 67, wherein said upper contact pad is electrically connected to the PCB via a connection member configured to maintain a mechanical connection to the PV cell and PCB during thermal expansion thereof.

69. A method according to claim 63, wherein said PV cells comprise two or more fiducial markers configured for facilitating automated placement of the cell on the PCB during manufacture of the module.

70. A method according to claim 63, wherein said PCB is configured to connect said PV cells in a total cross-tie topology.

71. A method for manufacture of a photovoltaic array, the method comprising:
a. providing a plurality of photovoltaic modules, each manufactured according to according to claim 63;
b. providing one or more support members carrying said modules, said support members being constituted by PCBs and being configured to electrically connect said modules; and
c. mechanically mounting and electrically connecting said photovoltaic arrays to said support member.

72. A method according to claim 71, wherein each of said modules comprises one or more connectors, and each of said support members comprising notches configured to receive said connectors.

73. A method according to claim 72, wherein each of said support members comprises a connection point to an electrically conductive layer thereof adjacent each of said notches, being disposed to contact a corresponding electrically conductive portion of the connector.

74. A photovoltaic module comprising one or more photovoltaic (PV) cells, each being configured to convert incident light into electrical energy, soldered to a printed circuit board (PCB) configured to electrically connect said PV cells to each other, wherein said PV cells and PCB are so configured and connected such that the module can withstand heating to a temperature sufficient to perform the soldering.

75. A photovoltaic module according to claim 74, wherein the soldering is reflow soldering.

76. A photovoltaic module according to claim 75, wherein said PCB comprises a pair of through-going apertures adjacent one another, giving rise to one or more cell-carrying portions therebetween, each carrying a PV cell, end portions of the PV cells being disposed over or within said through-going apertures.

77. A photovoltaic module according to claim 74, wherein each of the cells comprises, on a first, PCB-facing face thereof, a lower contact pad, and, on a second face opposite the first face, an upper contact pad, said contact pads being electrically connected to an electrically conductive layer of the PCB.

78. A photovoltaic module according to claim 77, wherein said upper contact pad is electrically connected to the PCB via a connection member configured to maintain a mechanical connection to the PV cell and PCB during thermal expansion thereof.

79. A photovoltaic module according to claim 77, wherein said PV cells comprise two lower contact pads.

80. A photovoltaic array comprising a plurality of photovoltaic modules according to claim 74, and one or more support members carrying said modules, said support members being constituted by PCBs and being configured to electrically connect said modules.

81. A photovoltaic array according to claim 80, wherein each of said modules comprises one or more connectors, and each of said support members comprising notches configured to receive said connectors.

82. A photovoltaic array according to claim 81, wherein each of said support members comprises a connection point to an electrically conductive layer thereof adjacent each of said notches, being disposed to contact a corresponding electrically conductive portion of the connector.
